(19) United States
(12) Patent Application Publication
(10) Pub. No.: US 2026/0150278 A1
(43) Pub. Date: May 28, 2026

(54) MASK PROGRAMMABLE ROM USING SHARED CONNECTIONS

(71) Applicant: Taalas Inc., Toronto (CA)

(72) Inventors: Ljubisa Bajic, Toronto (CA); Lejla Bajic, North York (CA); Dragoljub Ignjatovic, North York (CA)

(21) Appl. No.: 19/178,504

(22) Filed: Apr. 14, 2025

Related U.S. Application Data
(60) Provisional application No. 63/634,451, filed on Apr. 15, 2024.

(51) Int. Cl. H10B 20/00; G11C 17/12

(52) U.S. Cl. CPC H10B 20/387; G11C 17/12

(57) ABSTRACT

Methods and systems related to mask programmable memory using shared drain and gate connections are disclosed herein. A read only memory disclosed herein includes a transistor having a read terminal and a bit terminal. The read terminal and the bit terminal are a source and a drain of the transistor. The transistor also a word line coupled to a gate of the transistor, and a plurality of bit lines programmatically coupled to the bit terminal. The plurality of bit lines can be programmatically coupled by a set of mask programmable vias that couple the bit lines to the bit terminal.

### CROSS REFERENCE TO RELATED APPLICATION

This application claims the benefit of U.S. Provisional Ser. No. 63/634,451, titled “Mask Programmable ROM using Shared Drain Bit Line and Gate Word Line Connection,” and filed on Apr. 15, 2024, the entire content of which is incorporated by reference herein.

### TECHNICAL FIELD

This disclosure relates to computational architectures, in particular, to mask programmable memory using shared drain and gate connections and with memory density limited only by a metal pitch.

### BACKGROUND

The past years have seen rapid advancements in specialized computing architectures for applications such as cryptography, cloud computing, machine learning, and other applications. While these computing architectures continue to advance in terms of their ability to parallelize complex computations and execute specific computations more efficiently, few advancements have been made with respect to the memory used to store the data structures on which the complex computations are conducted. The lack of fundamental advancements has resulted in a dramatic increase in the relative cost of the memories required for these computing architectures to operate as compared to the cost of the computational components of the architecture. Estimates are that dynamic random-access memory (DRAM) is approximately 50% of the cost of most server systems and static random-access memory (SRAM) is approximately 50% of the cost of processor chips such as those used for machine learning, general computation, and graphics processing. Accordingly, random-access memory (RAM) is approximately 70% of the overall cost of certain computing architectures. As the data structures on which these computing architectures operate continue to increase in size, this disparity and the relative cost of memory (compared to the computational components of the architecture) will continue to increase.

DRAM and SRAM were first invented and described in the 1960s. Since then, there have been major improvements in the performance of DRAM and SRAM, and the feature size of cells (e.g., the smallest storage units in memory where data is stored) has been decreased with process improvements. However, relying on process improvements has not enabled memory to scale with the performance improvements of computational units. On one side, the performance of computational units improves according to Moore's Law, following a square law with decreases in feature size. Decreases in feature size of computational units may lead to decreases in power consumption per switch, increases in speed per switch, and increases in the density of the computational units of a computing architecture. On the other side, the same physical laws, when applied to memory cells, can only provide a linear benefit in terms of increasing the density of memory units. This is because power consumption per switch and switching speed per switch do not translate directly to a fundamental improvement in the operation of memory as an element for data storage. The lack of any architectural progress in random-access memory for these many years has led to a great disparity in the performance of memory cells as compared to computational units.

Hence, an approach for designing high-density memory systems may be desirable in improving memory to better support advanced computing architectures that increasingly parallelize and optimize complex computations.

### SUMMARY

To address the aforementioned shortcomings, methods and computing architectures related to mask programmable memory using shared connections are disclosed herein. In some embodiments, a read only memory includes a transistor having a read terminal and a bit terminal. The read terminal and the bit terminal are a source and a drain of the transistor. The read only memory also includes a word line coupled to a gate of the transistor, a first bit line routed over the bit terminal and not coupled to the bit terminal, and a second bit line routed over the bit terminal and coupled to the bit terminal. In some embodiments, a diode is used to couple the second bit line to the bit terminal. The read only memory may also include a pre-charge circuit coupled to the read terminal and configured to initiate a read operation to read data using the first bit line, the second bit line, and the word line, and a sense amplifier coupled to the read terminal and configured to output a value in the read operation.

In some embodiments, a read only memory includes a transistor having a read terminal and a bit terminal. The read terminal and the bit terminal are a source and a drain of the transistor. The read only memory also includes a word line coupled to a gate of the transistor and a plurality of bit lines programmatically coupled to the bit terminal. In some embodiments, the read only memory is programmed by making one or more changes to a mask during fabrication. The mask is adjusted to determine the one or more bit lines coupled to the bit terminal.

In some embodiments, the transistor and metal lines of the read only memory are same as transistors and metal lines used in any logic circuitry on a same substrate, where the metal lines include the word line and the plurality of bit lines. In some embodiments, each of the word line and the plurality of bit lines are shared by two or more transistors. In some embodiments, a number of the plurality of bit lines that are routed over and coupled to the bit terminal is determined by an inter-wire distance between adjacent bit lines of the plurality of bit lines. In some embodiments, the read only memory further includes a pre-charge circuit coupled to the read terminal and configured to initiate a read operation to read data using the plurality of bit lines and the word line, and a sense amplifier coupled to the read terminal and configured to output a value in the read operation.

In some embodiments, a method for programming a read only memory includes programmatically coupling a plurality of bit lines to a bit terminal of a transistor and coupling a word line to a gate of the transistor. The transistor has a read terminal and the bit terminal, and the read terminal and the bit terminal are a source and a drain of the transistor. In some embodiments, a plurality of diodes is used to connect one or more bit lines in the plurality of bit lines to the bit terminal.

In some embodiments, a method for reading a read only memory includes pre-charging a read line that is coupled to a read terminal of a transistor. The terminal and the bit terminal are a source and a drain of the transistor. The method also includes activating a word line that is coupled to a gate of the transistor, and activating a bit line from a plurality of bit lines programmatically coupled to a bit terminal of the transistor. The method further includes determining, by a sense amplifier, based on pre-charging the read line and activating the bit line and the word line, a value for output as a result of reading the read only memory.

In some embodiments, the method further includes preventing, using a diode, electrical current flows through a bit line in the plurality of bit lines subsequent to the activating of the word line. In some embodiments, activating the bit line comprises at least one of lowering a voltage on the bit line and creating a current sink to pull charge off the read line, or increasing the voltage on the bit line and creating a current source to push charge onto the read line. In some embodiments, determining, by the sense amplifier, the value comprises detecting a change of the voltage on the read line. The output value is indicated by at least one of a final voltage reached on the read line or an amount of time it takes for the voltage to change on the read line. In some embodiments, a number of values simultaneously read from the read only memory is limited by a number of sense amplifiers available and a number of transistors connected to the sense amplifiers. In some embodiments, each of the word line and the plurality of bit lines are shared by two or more transistors.

The above and other preferred features, including various novel details of implementation and combination of elements, will now be more particularly described with reference to the accompanying drawings and pointed out in the claims. It will be understood that the particular methods and apparatuses are shown by way of illustration only and not as limitations. As will be understood by those skilled in the art, the principles and features explained herein may be employed in various and numerous embodiments.

### BRIEF DESCRIPTION OF THE DRAWINGS

The disclosed embodiments have advantages and features which will be more readily apparent from the detailed description, the appended claims, and the accompanying figures (or drawings). A brief introduction of the figures is below.

FIG. 1 illustrates an exemplary representation of programmed cells of a ROM formed on a transistor, according to some embodiments.

FIG. 2 illustrates an exemplary structure and organization of a ROM array composed of transistors as shown in FIG. 1, according to some embodiments.

FIG. 3 illustrates an exemplary cross-sectional view of programmed cells of ROMs, according to some embodiments.

FIG. 4 illustrates a flow diagram for a read operation of a ROM, according to some embodiments.

### DETAILED DESCRIPTION

The Figures (FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles described herein.

### Overview

Disclosed herein are methods and systems for computer memories, specifically focusing on designing high-density read only memory (ROM) systems using advanced techniques in shared connections and modern semiconductor fabrication processes. In some embodiments, the methods and systems involve integrated ROM with shared connections, such as shared drain bit line connections and shared gate word line connections. The bit lines and word lines are critical components used to organize and access data stored in memory arrays (e.g., RAM, ROM). A bit line is a vertical conductor or wire in a memory array that connects to multiple memory cells within the same column, which enables data (e.g., bits) to be read from or written to a specific memory cell. For example, in a read operation, a bit line may sense and transmit a charge or voltage from an accessed memory cell. A drain may refer to one terminal of a transistor in a memory cell. A drain bit line may refer to a specific type of bit line that connects to the drain terminal of the transistor in each memory cell within a column, which makes a logical path for data transfer between the memory cell and external circuitry. A word line is a horizontal conductor in the memory array that connects to multiple memory cells in the same row, which selects which memory cells (e.g., row of memory cells) are accessed for a read or write operation. For example, a word line may be energized (e.g., set to high voltage) to activate all memory cells in a corresponding row to enable the data stored in these cells to be read out. A gate terminal regulates whether a transistor is turned on or off, i.e., conducting or non-conducting. A gate word line connects to the gate terminals of all transistors in a row of a memory array. When a specific gate word line is activated (e.g., by applying a voltage), the gate terminals of the transistors in that row are turned on, allowing data transfer between the memory cells in the row and their corresponding bit lines. By sharing the drain bit line connections and gate word line connections among multiple memory cells, the approach disclosed herein may reduce redundancy and optimize the physical layout of memory cells, thereby increasing memory density.

The memory, designed using the approaches disclosed herein, can have densities limited only by a metal pitch density of the process in which the memory is formed. Metal pitch is a distance between adjacent metal lines in a semiconductor process. It is a key factor in determining how small and dense the wiring can be in an integrated circuit. When the density of a ROM is limited only by this metal pitch, the memory design may maximally utilize the available wiring space within the process constraints. In a modern process with 3 nm processing nodes, the metal pitch is approximately 24 nm. In a next-generation process with 2 nm processing nodes, the metal pitch is expected to be approximately 20 nm. The processing nodes or semiconductor nodes (e.g., 3 nm and 2 nm) refer to the level of miniaturization in chip manufacturing. As the processing nodes shrink, smaller features (e.g., transistors, wiring) and/or higher density and performance may be enabled. Because the shared connections and efficient design approach described herein can maximize the use of the limited metal pitch, the ROMs can achieve extremely high densities through the semiconductor fabrication process with smaller nodes. By leveraging the advanced techniques and processes, the present approach may be employed to create ROMs with a minimal footprint (per memory cell) and improved scalability (as processing nodes shrink). This is particularly useful for applications requiring massive memory storage in a compact area, such as in modern processors, artificial intelligence (AI) accelerators, and embedded systems.

In some embodiments, the ROMs disclosed herein are mask programmable. This means that a ROM can be configured or programmed by making a change to a mask during semiconductor fabrication. A mask is a template used in photolithography to define patterns on the silicon wafer, such as creating connections between layers of material (e.g., metal layers, active regions, etc.).

In some embodiments, the ROMs disclosed herein may be programmable using a single mask change (e.g., during manufacturing). Vias are small vertical connections that link different layers of materials in a semiconductor device, such as connecting metal layers to active regions of semiconductor material. In the present disclosure, the mask may be used to form a set of vias that connect specific components of memory cells, for example, connecting a set of bit lines to a set of drains of the transistors that form the memory cells.

Furthermore, the transistors that form the memory cells disclosed herein can be the same types of transistors used for any other logic circuitry that may be implemented on the same semiconductor substrate. The metal lines used for interconnecting the transistors are also common to other logic circuitry on the substrate. Since the same transistors and metal lines can be used for both logic circuitry and the ROM cells, no additional processing steps are needed (e.g., the same basic processes used to create logic circuits can be reused to create the ROM), thereby simplifying manufacturing, reducing costs, and speeding up the production process.

The approaches disclosed herein are particularly applicable to machine learning applications in which a custom chip is fabricated to work with a particular machine learning model. The ROM memories disclosed herein are of high density, which can store more data in the same physical area, reduce the need for frequent data transfers between memory and storage, reduce power consumption, reduce data latency and improve parallel processing, etc. The present high-density ROM memories are well-suited for storing the model parameters that define machine learning models (e.g., filter values or weight values). This high density of ROMs is particularly advantageous for such applications, given the growing size of machine learning models. For example, GPT-3 has approximately 175 billion parameters, while GPT-4 is estimated to be defined by approximately 1.76 trillion parameters. Moreover, the ROMs described herein may be programmed using a limited number of mask modifications (e.g., a single mask modification), which allows a given production line to be easily customized for cost-effective manufacturing of integrated circuits that are optimized for a wide range of machine learning models.

### System Implementation

Methods and systems for memory (e.g., ROM) design disclosed herein can utilize shared drain and gate connections and push the limits of metal pitch in advanced fabrication processes. In some embodiments, the ROM is also mask programmable during fabrication. The present approach allows for extremely high-density ROMs, making it suitable for cutting-edge applications where memory density and efficiency are critical.

In some embodiments, a ROM may be formed using transistors. A transistor may include a drain region and a source region. Each of these regions corresponds to a terminal where current exists or enters the transistor. In some embodiments, either the source or the drain region may be connected to a set of bit lines using a set of mask-programmable connections. A bit line may be a conductive line (e.g., metal wiring line) and shared by multiple transistors in the ROM. The bit line is typically oriented perpendicular to the channel direction of the transistor. The gate of the transistor may serve as a word line in the ROM. This word line may be a conductive line (e.g., a polysilicon line or a combination of polysilicon and metal) that is also shared by multiple transistors in the ROM.

In some embodiments, a terminal of the transistor, opposite to the one programmably coupled to the bit lines, can be used to read the values stored by the transistor. In the disclosure hereafter, the terminal that is programmably coupled to the bit lines may be referred to as a drain terminal, and the opposite terminal that is used to read the values stored by the transistor may be referred to as a source terminal. It should be noted, however, that the drain and source can be interchanged in this regard depending upon the implementation. The drain and source terminals may be referred to hereafter as the conductive terminals of the transistor. The conductive terminal to which the bit lines are programmatically connected may be referred to as a bit terminal. The conductive terminal opposite to the bit terminal may be referred to as a read terminal.

The present disclosure optimizes the data-storing capability of transistors in ROM, particularly in multivalued or high-density configurations. In some embodiments, each transistor in the ROM may store a number of values equal to the number of bit lines that can be programmatically connected to its bit terminal. For example, if a transistor is connected to three bit lines, it may represent three different states or values. In cases where each cell of the ROM is multivalued, the number of values a transistor may store is the product of the number of bit lines programmatically connected to the bit terminal and the number of potential values per cell. For example, if each cell can represent two values and the transistor is connected to three bit lines, the transistor can store a total of six values.

In some embodiments, each transistor in the ROM may store three or more values as the bit terminal of the transistor may be programmatically connected to three or more bit lines. The number of potential values per cell may be limited by the physical constraints of routing bit lines over the bit terminal. The minimum inter-wire pitch of the conductive layer (e.g., the distance between conductive lines) may determine the number of bit lines that can be routed over the bit terminal. In advanced manufacturing processes, where the inter-wire pitch is very small (e.g., 20 nm or less), it becomes feasible to route more bit lines, enabling each transistor to store more values with higher density.

In some embodiments, the number of potential values per cell may also be limited by the amount or size of the active area dedicated to forming the bit terminal. A larger active area may theoretically accommodate more bit values, but increased resistance in the active area can affect performance, and leakage current from the bit terminal to the transistor's body can become significant as the active area grows, reducing efficiency and reliability. The ROM design described herein may balance the number of bit lines and active area size against potential performance issues (e.g., resistance, leakage).

In some embodiments, the mask-programmable connections may be connections between a layer of conductive material (e.g., a metal layer) and the bit terminal of a transistor. The bit terminal typically refers to an active region of a semiconductor substrate that has been doped to serve as the drain or source of the transistor. The connections may be formed using vias, which are small holes or channels filled with conductive material to electrically link different layers of the transistor. The connections can be mask-programmable in that changing a mask used in the fabrication process of the transistor can control the pattern of connections between the bit lines and the bit terminals. For example, a via can be created between a bit line and a bit terminal or left unconnected based on the change of a mask. In some embodiments, the mask-programmable connections can involve a change in one mask, where the mask may determine whether conductive material is deposited at specific via locations, making the via conductive or non-conductive. In these embodiments, other process steps associated with the formation of the vias may still be conducted in all the potential locations for the vias. That is, potential via locations may undergo the same fabrication steps (e.g., etching and deposition processes). However, a single mask can selectively prevent the formation of conductive connections at specific locations, thereby controlling which bit lines are linked to bit terminals. In some embodiments (as described below), the connections may include diodes to control current flow. The diodes may prevent current from passing through a connection unless the associated bit line is activated. Examples of diodes may include Schottky diodes or PN-diodes that are formed at a semiconductor injunction between the bit terminal and the via.

The mask-programmability described herein provides a flexible and reliable way to program ROMs at the hardware level, balancing high density with precise control over current flow. The mask-programmable connections enable customizability in ROM design, as the mask can determine the stored data pattern. The inclusion of diodes provides additional control over current flow, improving the functionality and preventing unintended interactions between bit lines and bit terminals.

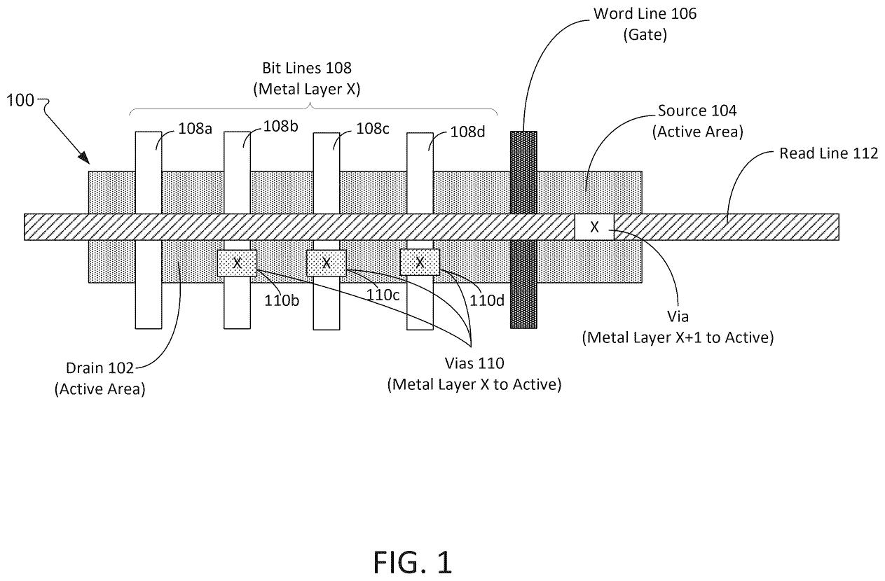

FIG. 1 illustrates an exemplary representation of programmed cells of a ROM formed on a transistor 100, according to some embodiments. In this example, five programmed cells formed by the same transistor 100 are depicted. Transistor 100 includes a drain region 102 in a doped area of the substrate, forming part of the active area of the transistor. Drain region 102 acts as the bit terminal of transistor 100, which connects to bit lines through programmable vias and is used for storing data in the ROM. Transistor 100 also includes a source 104 located in another region of the substrate that has been doped to serve as the active area of transistor 100. Source region 104 serves as the read terminal of transistor 100, connecting to a read line of the ROM through a via. This allows the stored data to be accessed during a read operation. A read line is a conductive path that carries signals from ROM cells to a sense amplifier (described below) for data interpretation, which may connect to multiple read terminals of multiple transistors when the ROM includes multiple transistors. Transistor 100 further includes a gate, which may be a conductive strip (e.g., doped polysilicon or metal) placed above a channel of transistor 100. The gate controls the flow of current between drain 102 and source 104, enabling or disabling the reading of stored data.

Transistor 100 in FIG. 1 may be programmed through the programmatic formation of the vias, which selectively connect the bit lines to the bit terminal (e.g., 102). The selective connections determine the binary or multivalued data stored by transistor 100. In some embodiments, the lowest metal layer (e.g., metal one layer) may form bit lines 108, and the vias may connect the lowest metal layer or bit lines 108 to the active area of transistor 100. In the illustrated example, three of the four bit lines 108b, 108c, and 108d are connected to the active area through the introduction vias 110b, 110c, and 110d at the intersection of the bit lines and the bit terminal 102, while a fourth bit line 108a is not connected to the active area through a via. A connection represents a programmed state (e.g., “1” or a multi-valued state). The lack of connection represents a different programmed state (e.g., “0”). When transistor 100 is activated, no current flows between bit line 108a and read line 112 because the circuit is incomplete (no electrical path exists between bit line 108a and bit terminal 102).

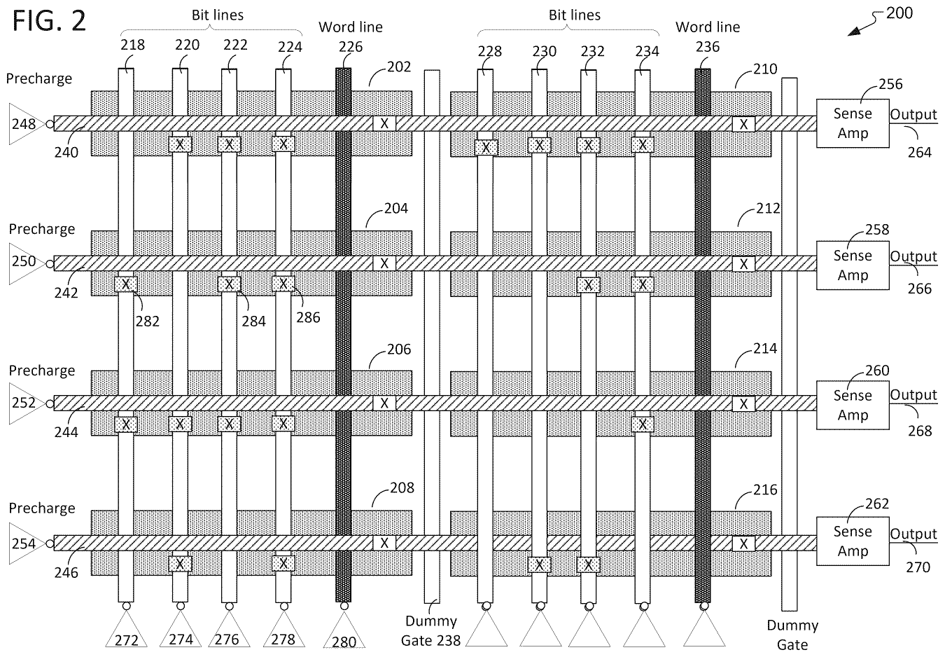

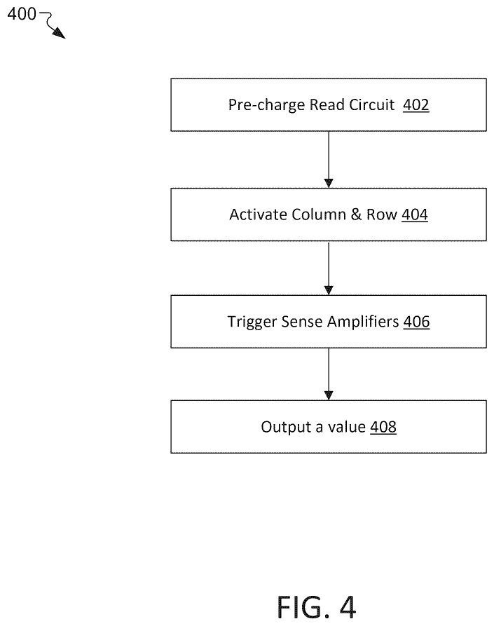

A notable aspect is that the connection described herein may represent a multi-bit state or value. For example, a bit line (e.g., 218 in FIG. 2 described below) can be used to shift through (e.g., sequentially transmit) a multi-bit value (e.g., 10 bits) by repeatedly performing the sense flow outlined in below FIG. 4. Importantly, this can be achieved without modifying the circuits illustrated in the accompanying diagrams. This approach is beneficial since it enables the integration of a more compact ROM structure across various use cases to support efficient data communication. For example, U.S. patent application Ser. No. 19/014,806, filed Jan. 9, 2025, introduces a connectivity mesh configuration, where multiplier circuits, readable cells, a read circuit, and a selection circuit are interconnected for efficient, scalable communication. In particular, the readable cells may be configured similarly to a ROM cell. Each of the readable cells may include an access transistor that is coupled to a bit line, and these bit lines can be used to pass precomputed values from a side table to outputs of a macro. By enabling multiple values to be sensed through a shared connection, the ROM implementation described herein aligns well with and supports the connectivity mesh-based scheme proposed in this patent application.

For clarity in the illustration, the vias 110b, 110c, and 110d in FIG. 1 are depicted off-center of the active area. However, in actual fabrication, the vias may be located in the center of the active area directly beneath a read line 112. This layout is possible because read line 112 can be in a higher metal layer (e.g., metal two layer) that is routed over the lower metal layer (e.g., metal one layer) and its vias and does not obstruct the vias. In general, read line 112 may be part of any higher metal layer as long as it does not interfere with the lower metal layers, including the vias connecting the bit lines to the bit terminal of the transistor. This design allows the ROM to store data efficiently (e.g., by selectively introducing vias to connect specific bit lines to the bit terminal) while maintaining clarity and avoiding conflicts between layers (e.g., by locating the read line in a higher metal layer and bit lines in a lower metal layer).

The process of reading data from a ROM cell that uses a transistor structure in FIG. 1 is described herein. This process may include activating word line 106 and one of bit lines 108. Word line 106 may be connected to the gate of the transistor, which controls the conductivity of a transistor channel. A specific voltage may be applied to activate word line 106. The voltage may depend on the polarity of the transistor (e.g., n-type or p-type) and/or characteristics of the transistor (e.g., a threshold voltage required to turn on the transistor). Once the word line is activated, a conductive electrical path through the channel of the transistor may be formed, such that the bit terminal (e.g., drain 102) is coupled or connected to the read terminal (e.g., source 104). The activation of a bit line enables the transfer of charge between the bit terminal (e.g., drain 102) and read line 112, enabling the determination of the stored value. Activating a bit line also involves applying a voltage. This voltage may depend on the polarity and characteristics of the transistor as well as the characteristics of a read circuit. The read circuit is used to extract the stored data from memory cells by sensing and interpreting electrical signals.

The characteristics of the read circuit may impact what voltage is required to activate a bit line. In some embodiments, the read circuit may monitor voltage changes (e.g., rise or drop) on read line 112 to determine whether a connection exists between the bit terminal (via the bit line) and the active area. For example, in the case of current sink configuration, the read circuit may be configured to detect a voltage drop on read line 112. Activating a bit line may include lowering the voltage on the bit line and creating a current sink to pull charge off read line 112. In such a configuration, if the voltage on read line 112 does not drop in response to reading a cell, the read circuit may be able to determine that no connection was formed between the bit line and the active area, and accordingly, a first value (e.g., “0”) may be read from memory. However, if the voltage on read line 112 drops in response to reading the cell, the read circuit may determine a connection was formed between the bit line and the active area. A second value (e.g., “1”) may be read from memory. The presence or absence of the connection corresponds to values (e.g., binary values), allowing the ROM to store and retrieve data effectively. As another example, in the case of current source configuration, the read circuit may be configured to detect a voltage rise on read line 112. Activating a bit line may include increasing the voltage on the bit line and creating a current source to push charge onto read line 112 through the connection to the bit line. In this configuration, when the voltage on read line 112 does not rise in response to reading a cell, the read circuit may determine that no connection was formed between the bit line and the active area. As a result, a first value may be read from memory. However, when the voltage on read line 112 rises, the read circuit may determine a connection exists between the bit line and the active area, and a second value may be read from memory.

A memory cell may be multivalued, representing three or more states rather than representing one of two states (e.g., “0” or “1”). In this case, the final voltage reached on read line 112 or the time it takes for the voltage to change on read line 112 may indicate the conductivity of the connection to the bit line. For example, a higher conductivity may be indicated by a faster voltage change or a higher final voltage. The variations in voltage or timing correspond to distinct stored values. The read circuit may measure voltages or timing that represent specific values, and multi-valued data may be read from memory.

In some embodiments, the transistors described above (e.g., in FIG. 1) may be arranged in an array to form a ROM memory. Each individual cell of the memory may be addressed by activating a specific combination of a word line and a bit line. In some embodiments, the transistors and conductive lines that form the memory (e.g., ROM) cells disclosed herein can be the same type of transistors and conductive lines used for any logic circuitry that may be implemented on the same substrate. Therefore, the same fabrication steps used for logic circuitry may also be used for the ROM, and no extra or specialized processing steps are necessary in forming the ROMs described herein. Instead, the masks used in the fabrication process may be modified to adjust the ROM layout. For example, the bit terminal in ROM cells may be larger in dimension than the corresponding transistor terminals in the logic circuitry of the same substrate. The masks used to define the layout of the bit terminal may be adjusted to increase the size of the bit terminal, while keeping all other processing steps the same. Alternatively or additionally, a processing step or set of steps may be utilized to account for the larger dimension of the bit terminal. For example, the dose of the dopants used to form the bit terminal may be adjusted to optimize the electrical properties of the larger bit terminal, ensuring the larger dimension does not affect the overall substrate design.

FIG. 2 illustrates an exemplary structure and organization of a ROM array 200 composed of transistors (e.g., transistor 100 shown in FIG. 1). A section of a ROM with eight transistors (e.g., 202, 204, 206, 208, 210, 212, 214, and 216) is depicted, where a set of word lines and bit lines form a grid structure, enabling specific memory cells or transistors to be addressed and programmed. These transistors (e.g., 202 through 216) are programmed with different patterns of connections between the bit lines and the bit terminal of the transistors. In FIG. 2, the transistors per column share the same conductive lines. For example, the column of transistors 202, 204, 206, and 208 may share the same bit lines 218, 220, 222, and 224 for their bit terminals and share the same word line 226 for their gates. Likewise, the column of transistors 210, 212, 214, and 216 may share the same bit lines 228, 230, 232, and 234 for their bit terminals and share the same word line 236 for their gates. This sharing may simplify the ROM design and minimize the number of conductive lines needed, improving layout efficiency.

The inter-row spacing of the array, or the distance between adjacent rows, may also be constrained. In the example of FIG. 2, this spacing is limited solely by the minimum allowed distance between the source and drain regions of adjacent transistors. The spacing can be a small distance in modern processors, enabling a highly compact configuration and increasing memory density. As depicted in FIG. 2, adjacent columns of transistors in the ROM can be separated by dummy gates. A dummy gate is an unused gate placed between columns for structural or electrical isolation. For example, transistors 202, 204, 206, and 208 in the left column may be separated from transistors 210, 212, 214, and 216 in the adjacent right column by a dummy gate 238. The source and drain regions of transistors in adjacent columns may be placed in close proximity to each other to maximize space efficiency.

As to the operation of the ROM in FIG. 2, the read lines (e.g., 240, 242, 244, and 246) may be initialized using corresponding pre-charge buffers (e.g., 248, 250, 252, and 254) before accessing the memory. This pre-charging prepares the read lines for accurate sensing during reading operations. In some embodiments, the read lines may be pre-charged to different states or voltages, such as a high voltage, a low voltage, or a tri-state value (a state with no active drive), depending upon the characteristics of the ROM. Subsequent to the pre-charging, a specific combination of a word line and bit line(s) may be activated. A set of values may then be read from a column of transistors of the ROM that is associated with the activated word line. In the example of FIG. 2, depending on which word line 226 or 236 is activated, four values may be read from a set of four transistors (either transistors 202, 204, 206, and 208, or transistors 210, 212, 214, and 216).

The state of memory cells determines whether charge is moved to or from the read lines via the transistors that are activated through the word line (e.g., 226 or 236). If a connection was formed between a bit line and a bit terminal for an activated cell, the bit line may move charge to or from a read line to cause a detectable change in voltage on the read line. On the other side, if a connection does not exist, no charge flows and the read line voltage may remain unchanged. In the example of FIG. 2, a column of four transistors may store and provide four values at once, depending on the state of each transistor. The data may be read based on monitoring the behavior of the read lines (e.g., voltage drop or rise) connected to the selected column of transistors.

In some embodiments, the voltage on the read lines may be monitored by sense amplifiers (e.g., 256, 258, 260, and 262). The sense amplifiers may detect changes caused by charge movement (or the lack thereof) and interpret the voltage levels. After the read period, the sense amplifiers may output the interpreted values to the designated output lines (e.g., 264, 266, 268, and 270). The number of values that can be simultaneously read is thereby only limited by the number of sense amplifiers available and the number of transistors per column connected to those sense amplifiers.

As discussed above, the connections between the bit lines and bit terminals may include diodes. The diodes may be used to block unintended current leakage by preventing charge from moving through a connection to a bit line that is not activated. For example, with reference to FIG. 2, suppose the bit line 224 associated with bit line buffer 278 is activated (e.g., by applying a high voltage). If a transistor (e.g., 208) is an n-type transistor with the drain serving as the bit terminal, precautions are needed to avoid electrical current leaking to other bit lines (e.g., 220) of the transistor through the connection to the bit lines associated with bit line buffers (e.g., 274). A bit line buffer (e.g., 272, 274, 276, and 278) is a circuit component that helps manage and control the bit lines during read and write operations (e.g., ensuring appropriate voltage or current, preventing interferences, etc.). As such, the diodes of the connections can allow the current to flow exclusively to or from the bit terminal when an associated bit line is activated.

In some embodiments, a threshold voltage of a diode may be configured high enough to block leakage currents under normal conditions (inactive bit lines), while still significantly lower than the differential voltage formed across the diode when the bit line is activated (ensuring the conductivity of diode when required). In the case of the n-type transistor mentioned above with a bit line activated on a high voltage, the diode/transistor may be configured as a pn-junction diode/transistor, where the n-type material is on the bit terminal side of the junction, and the p-type material is on the bit line side of the junction.

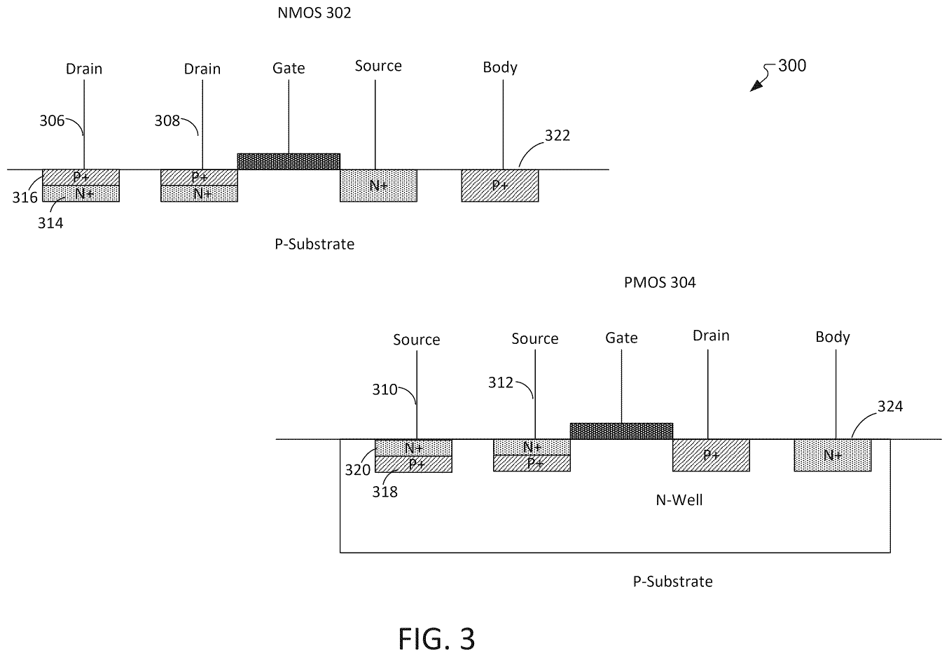

FIG. 3 illustrates an exemplary cross-sectional view 300 of programmed cells of ROMs, according to some embodiments. In this example, cross-sections of two programmed cells are depicted to show how a transistor may be implemented in either NMOS (e.g., 302) or PMOS (e.g., 304). As illustrated, there are only two connections to the bit terminal in both devices, for example, connections 306 and 308 in NMOS 302, and connections 310 and 312 in PMOS 304. However, there could be many more connections to the bit terminal. In both cross-sections (e.g., 302 and 304), the bit terminal has a counter-doped contact region with the opposite doping to the bit terminal. In the case of NMOS 302, n-type doping 314 is used in the bit terminal, and the counter-doped contact is a strong P+ doped region 316. In the case of PMOS 304, p-type doping 318 is used in the bit terminal, and the counter-doped contact is a strong N+ doped region 320. In both cases, the added doped contact region (e.g., 316 or 320) forms a diode with the required polarity to ensure that current does not flow between the bit line and the bit region when the bit line is not activated. The counter-doped contact region (e.g., 316 or 320) in NMOS and PMOS transistors (e.g., 302 or 304) forms a pn-junction diode at the bit terminal. This diode is configured to be reverse-biased when the bit line is not activated, preventing leakage currents. In NMOS 302, a bit line may be set to a low voltage, and the bit terminal may be pre-charged to a higher voltage than the bit line such that the pn-junction diode formed by the P+ counter-doped contact region 316 and the n-doped bit terminal 314 is reverse-biased (no current flows). As a result, this diode blocks current flow between the bit line and the bit terminal when the bit line is not activated. In PMOS 304, the bit line may be set to a high voltage, and the bit terminal may be pre-charged to a lower voltage than the bit line. Here, a pn-junction diode is also configured to be reverse-biased, which blocks current flow when the bit line is inactivated.

In some embodiments, the counter-doped contact regions (e.g., 316 and 320) for the transistors, NMOS 302 and PMOS 304 in the example of FIG. 3, can be formed without any additional processing step because these regions are formed using the same mask and implantation process as used to form the body contact or well contact for the transistors. For example, the P+ doped region 322 that forms the substrate contact of NMOS 302 may be formed by an implant process that is also used to form the P+counter-doped contact region 316 in the bit terminal. As another example, the N+counter-doped contact region 324 that forms the well contact of PMOS 304 may be formed by an implant process that is also used to form the N+ counter-doped contact region 320 in the bit terminal. Alternatively or additionally, one or more of the implant, mask, or processing steps may be utilized to form the counter-doped contacts (e.g., 316 and 320). The configuration shown in FIG. 3 may ensure the reliable and efficient operation of the ROM cells.

FIG. 4 illustrates a flow diagram 400 for a read operation of a ROM, according to some embodiments. In this flow diagram, steps are outlined to show how data from a column of transistors associated with a specific word line may be read over multiple cycles. In some embodiments, flow diagram 400 may be applied to read the four bits associated with a set of four bit lines and a word line of the ROM shown in FIG. 2. The word line may be 226 or 236. One set of bit lines may include bit lines 218, 220, 222, and 224 associated with word line 226. Another set of bit lines may be 228, 230, 232, and 234 associated with word line 236. In each cycle through the flow chart, one bit line's worth of bits may be read. In the example of FIG. 2, when a word line 226 or 236 is activated, this would result in four bits being read per cycle and 16 bits being read over the course of four cycles.

Flow diagram 400 starts with pre-charging a read circuit at step 402. This includes initializing the read lines (e.g., 240, 242, 244, and 246 in FIG. 2) to prepare for the read operation, ensuring that any voltage change in the read operation is detectable. Next, at step 404, a word line may be activated. This turns on the transistor(s) in that row, which enables a connection between the bit terminal(s) (drain/source) and the read terminal(s) of the row. One or more bit lines may be activated, which determines the stored value/bits to be read. A bit line is monitored to determine if a connection exists. If a connection exists, current can flow through the transistor, causing a voltage drop or rising on a read line. If no connection exists, the current does not flow, and the read line voltage remains unchanged.

The read process in flow diagram 400 continues with triggering sense amplifiers at step 406. A sense amplifier may detect the voltage change on the read line, for example, by comparing the voltage on the read line (changed or unchanged through the bit line connection) to the pre-charge low value. Depending upon the comparison result, the sense amplifier may determine a value of “0” or “1,” and output this detected bit as the stored ROM value at step 408. For example, if there is a voltage change (drop or rise) compared to the pre-charged low value, the output value may be “1.” Otherwise, the value is “0 .” In some embodiments, the steps of flowchart 400 may be controlled in a self-timed manner (e.g., delay lines) or by a clocked state machine. The steps can then be repeated to read multiple bits (e.g., the values associated with the next bit lines). In particular, a different bit line will be activated to the exclusion of the other bit lines. The read process repeats for all memory cells.

Suppose the ROM in FIG. 2 includes NMOS transistors. For example, in the first reading cycle, read line 242 is pre-charged to a low voltage using pre-charge buffer 250. When word line 226 is driven to a high voltage using pre-charge buffer 276, transistor 204 is turned on. If bit line 218 is activated with a high voltage using pre-charge buffer 272, this would cause a voltage change (drop or rise) in read line 242 because of the electrical connection associated with bit line 218, as represented by a via 282. The corresponding sense amplifier 266 may then detect this voltage change, and provide a value “1” on output line 266, which is the value read from the ROM. Next, bit lines 220, 222, and 224 may be activated sequentially, using corresponding pre-charge buffers 274, 276, and 278. Since connections exist, as reflected by vias 284 and 286, when bit lines 222 and 224 are activated, 1s are read, whereas a “0” is read when bit line 220 is activated without forming an electrical path. As a result, a “1, 0, 1, 1” may be read when transistor 204 is turned on subsequent to the pre-charge of the read line 242 and the activation of word line 226 in the first cycle. The read process may repeat for each memory cell of the ROM shown in FIG. 2 in multiple cycles. In some embodiments, a row (transistors sharing a word line) will be read in one cycle, while subsequent rows can be read in subsequent cycles.

### Additional Considerations

While the specification has been described in detail with respect to specific embodiments of the invention, it will be appreciated that those skilled in the art, upon attaining an understanding of the foregoing, may readily conceive of alterations to, variations of, and equivalents to these embodiments. Any of the method steps discussed above can be conducted by a processor operating with a computer-readable non-transitory medium storing instructions for those method steps. The computer-readable medium may be memory within a personal user device or a network accessible memory. Although examples in the disclosure were generally directed to machine intelligence applications, the same approaches could be utilized to other computationally intensive applications including cryptographic computations, ray tracing computations, and others. As another example, although examples in the disclosure were generally directed to computations in which multiplication operations must be conducted on a data structure with a number of parameters that is much larger than the potential values of those parameters, the same approaches can be used for different operations in place of the multiplication such as division, subtraction, addition, roots, logarithms, exponents, factorials, and any other mathematical or logical operation. These and other modifications and variations to the present invention may be practiced by those skilled in the art, without departing from the scope of the present invention, which is more particularly set forth in the appended claims.

### Terminology

The phraseology and terminology used herein is for the purpose of description and should not be regarded as limiting.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Each numerical value presented herein, for example, in a table, a chart, or a graph, is contemplated to represent a minimum value or a maximum value in a range for a corresponding parameter. Accordingly, when added to the claims, the numerical value provides express support for claiming the range, which may lie above or below the numerical value, in accordance with the teachings herein. Absent inclusion in the claims, each numerical value presented herein is not to be considered limiting in any regard.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. The features and functions of the various embodiments may be arranged in various combinations and permutations, and all are considered to be within the scope of the disclosed invention. Accordingly, the described embodiments are to be considered in all respects as only illustrative and not restrictive. Furthermore, the configurations, materials, and dimensions described herein are intended as illustrative and in no way limiting. Similarly, although physical explanations have been provided for explanatory purposes, there is no intent to be bound by any particular theory or mechanism, or to limit the claims in accordance therewith.

What is claimed is:

1. A read only memory comprising:
a transistor having a read terminal and a bit terminal, wherein the read terminal and the bit terminal are a source and a drain of the transistor;
a word line coupled to a gate of the transistor;
a first bit line routed over the bit terminal and not coupled to the bit terminal; and
a second bit line routed over the bit terminal and coupled to the bit terminal to form a connection.

2. The read only memory of claim 1, further comprising:
a diode configured to couple the second bit line to the bit terminal.

3. The read only memory of claim 1, further comprising:
a pre-charge circuit coupled to the read terminal and configured to initiate a read operation to read data using the first bit line, the second bit line, and the word line; and
a sense amplifier coupled to the read terminal and configured to output a value in the read operation.

4. The read only memory of claim 1, where the connection represents a multi-bit value.

5. A read only memory comprising:
a transistor having a read terminal and a bit terminal, wherein the read terminal and the bit terminal are a source and a drain of the transistor;
a word line coupled to a gate of the transistor; and
a plurality of bit lines programmatically coupled to the bit terminal.

6. The read only memory of claim 5, further comprising:
a plurality of diodes configured to connect one or more bit lines in the plurality of bit lines to the bit terminal.

7. The read only memory of claim 6, wherein the read only memory is programmed by making one or more changes to a mask during fabrication.

8. The read only memory of claim 7, wherein the mask is adjusted to determine the one or more bit lines coupled to the bit terminal.

9. The read only memory of claim 5, wherein the transistor and metal lines of the read only memory are same as transistors and metal lines used in any logic circuitry on a same substrate, wherein the metal lines include the word line and the plurality of bit lines.

10. The read only memory of claim 5, wherein each of the word line and the plurality of bit lines are shared by two or more transistors.

11. The read only memory of claim 5, wherein a number of the plurality of bit lines that are routed over and coupled to the bit terminal is determined by an inter-wire distance between adjacent bit lines of the plurality of bit lines.

12. The read only memory of claim 5, further comprising:
a pre-charge circuit coupled to the read terminal and configured to initiate a read operation to read data using the plurality of bit lines and the word line; and
a sense amplifier coupled to the read terminal and configured to output a value in the read operation.

13. A method for programming a read only memory comprising:
programmatically coupling a plurality of bit lines to a bit terminal of a transistor; and
coupling a word line to a gate of the transistor,
wherein the transistor has a read terminal and the bit terminal, and the read terminal and the bit terminal are a source and a drain of the transistor.

14. The method of claim 13, wherein a plurality of diodes is used to connect one or more bit lines in the plurality of bit lines to the bit terminal.

15. A method for reading a read only memory comprising:
pre-charging a read line that is coupled to a read terminal of a transistor;
activating a word line that is coupled to a gate of the transistor;
activating a bit line from a plurality of bit lines programmatically coupled to a bit terminal of the transistor; and
determining, by a sense amplifier, based on pre-charging the read line and activating the bit line and the word line, a value for output as a result of reading the read only memory,
wherein the read terminal and the bit terminal are a source and a drain of the transistor.

16. The method of claim 15, further comprising:
preventing, using a diode, electrical current from flowing through a bit line in the plurality of bit lines subsequent to the activating of the word line.

17. The method of claim 15, wherein activating the bit line comprises at least one of:
lowering a voltage on the bit line and creating a current sink to pull charge off the read line, or
increasing the voltage on the bit line and creating a current source to push the charge onto the read line.

18. The method of claim 17, wherein determining, by the sense amplifier, the value comprises detecting a change of the voltage on the read line.

19. The method of claim 17, wherein the value is indicated by at least one of a final voltage reached on the read line or an amount of time it takes for the voltage to change on the read line.

20. The method of claim 15, wherein a number of values simultaneously read from the read only memory is limited by a number of sense amplifiers available and a number of transistors connected to the sense amplifiers.

21. The method of claim 15, wherein each of the word line and the plurality of bit lines are shared by two or more transistors.
